(19) United States
(12) Patent Application Publication
(10) Pub. No.: US 2016/0079167 A1
(43) Pub. Date: Mar. 17, 2016

(54) TIE-OFF STRUCTURES FOR MIDDLE-OF-LINE (MOL) MANUFACTURED INTEGRATED CIRCUITS, AND RELATED METHODS

(71) Applicant: QUALCOMM Incorporated, San Diego, CA (US)

(72) Inventors: John Jianhong Zhu, San Diego, CA (US); Kern Rim, San Diego, CA (US); Stanley Seungchul Song, San Diego, CA (US); Jeffrey Junhao Xu, San Diego, CA (US)

(21) Appl. No.: 14/484,353

(22) Filed: Sep. 12, 2014

(51) Int. Cl. H01L 23/535; H01L 21/768; H01L 27/06

(52) U.S. Cl. CPC H01L 23/535; H01L 27/0688; H01L 21/76895

(57) ABSTRACT

Tie-off structures for middle-of-line (MOL) manufactured integrated circuits, and related methods are disclosed. As a non-limiting example, the tie-off structure may be used to tie-off a drain or source of a transistor to the gate of the transistor, such as provided in a dummy gate used for isolation purposes. In this regard in one aspect, a MOL stack is provided that includes a metal gate connection that is coupled to a metal layer through metal structure disposed in and above a dielectric layer above a gate associated with the metal gate connection. By coupling the metal gate connection to the metal layer, the gate of a transistor may be coupled or “tied-off” to a source or drain element of the transistor. This may avoid the need to etch the metal gate connection provided below the dielectric layer to provide sufficient connectivity between the metal layer and the metal gate connection.

### BACKGROUND

I. Field of the Disclosure

The technology of the disclosure relates generally to facilitating interconnections between elements formed from middle-of-line (MOL) processes within an integrated circuit.

II. Background

Computing devices have become commonplace throughout society. The increasing presence of such computing devices has accelerated in part because of the increasing functionality and versatility of such computing devices. The increase in functionality and versatility has been enabled by providing increasingly powerful processing capabilities in small packages as loosely recognized by Moore's Law. The pressures to increase processing capabilities while decreasing the size of the integrated circuits (ICs) have strained conventional manufacturing processes, especially as the node size within ICs has been reduced to low nanometer (nm) dimensions (e.g., <20 nm).

Current semiconductor fabrication of ICs may include front-end-of-line (FEOL), middle-of-line (MOL), and back-end-of-line (BEOL) processes. The FEOL processes may include wafer preparation, isolation, well formation, gate patterning, spacer, extension, and source/drain implantation, silicide formation, and the like. The MOL processes may include gate contact formation and interconnection between differing layers of the ICs. The BEOL processes may include a series of wafer processing steps for interconnecting semiconductor devices created during the FEOL and MOL processes. Successful fabrication and qualification of modern semiconductor chip products involves an interplay between the materials and the processes employed. In particular, gate contact formation during the MOL process is increasingly challenging at the current low nanometer node sizes, particularly for lithography printing.

Accordingly, alternate manufacturing processes for providing gate contact formation may be helpful in facilitating ICs at low nanometer (nm) node sizes. With such varied manufacturing processes, circuit designers may focus on other areas to improve miniaturization and increase functionality of ICs. For example, gate tie-off can be an important feature in advanced IC technology nodes to improve chip scaling when continuous active regions are provided in an IC between abutted transistors. Effective and process friendly gate tie-off is desired.

### SUMMARY OF THE DISCLOSURE

Aspects disclosed in the detailed description include tie-off structures for middle-of-line (MOL) manufactured integrated circuits, and related methods. As a non-limiting example, the tie-off structure may be used to tie-off a drain or source of a transistor to the gate of the transistor, such as provided in a dummy gate used for isolation purposes. In this regard in one aspect, a MOL stack is provided that includes a metal gate connection and is coupled to a metal layer through a metal structure disposed in and above a dielectric layer above a gate associated with the metal gate connection. By coupling the metal gate connection to the metal layer, the gate may be coupled or “tied-off” to a source or drain element of a transistor of which the gate is an element. As an example, moving the coupling to in and above the dielectric layer of the MOL stack helps avoid the need to etch the metal gate connection provided below the dielectric layer to provide sufficient connectivity between the metal layer and the metal gate connection, thus simplifying the manufacturing of integrated circuits (ICs), particularly at low nanometer node sizes.

In this regard in one aspect, a MOL stack in an IC is disclosed. The MOL stack comprises a substrate. The MOL stack also comprises a gate structure of a transistor overlying the substrate. The gate structure comprises a gate region coupled to the substrate. The gate structure also comprises a metal gate connection overlying the gate region. The MOL stack also comprises a first metal layer overlying the substrate, the first metal layer coupled to one of a drain or source of the transistor. The MOL stack further comprises a dielectric layer overlying the gate structure and the first metal layer. The MOL stack also comprises a metal structure disposed in and above the dielectric layer, the metal structure electrically coupled to the metal gate connection and the first metal layer.

In another aspect, a MOL stack in an IC is disclosed. The MOL stack comprises a substrate. The MOL stack comprises a gate structure of a transistor overlying the substrate. The gate structure comprises a gate region coupled to the substrate. The gate structure also comprises a metal gate connection overlying the gate region. The MOL stack also comprises a first metal layer overlying the substrate, the first metal layer coupled to one of a drain or source of the transistor. The MOL stack further comprises a dielectric layer overlying the gate structure and the first metal layer. The MOL stack also comprises a means for electrically coupling the metal gate connection to the first metal layer, the means for electrically coupling disposed in and above the dielectric layer.

In another aspect, a method of forming a MOL stack in an IC is disclosed. The method comprises during a front-end-of-line (FEOL) process, providing a substrate. The method also comprises during the FEOL process, providing a gate structure of a transistor overlying the substrate. The gate structure comprises a gate region coupled to the substrate and a metal gate connection overlying the gate region. The method also comprises during the FEOL process, providing a first metal layer overlying the substrate, the first metal layer coupled to one of a drain or source of the transistor. The method also comprises during the FEOL process, providing a dielectric layer overlying the gate structure and the first metal layer. The method further comprises during a MOL process, providing a metal structure disposed in and above the dielectric layer. The method also comprises coupling the metal gate connection and the first metal layer with the metal structure.

In another aspect, a MOL stack in an IC is disclosed. The MOL stack comprises a transistor comprising a gate and at least one of a source and a drain. The MOL stack also comprises a first metal layer coupled to the at least one of the source and the drain. The MOL stack also comprises a gate connection coupled to the gate. The MOL stack further comprises a dielectric layer above the transistor, the first metal layer and the gate connection. The MOL stack also comprises a metal structure positioned in and above the dielectric layer electrically coupling the first metal layer with the gate connection.

### BRIEF DESCRIPTION OF THE FIGURES

FIG. 1 is a block diagram of an exemplary complementary metal oxide semiconductor (CMOS) integrated circuit (IC) that may incorporate aspects of the present disclosure;

FIG. 2 is a simplified cross-sectional view of a conventional three-dimensional (3D) IC (3DIC) with vias and metal layers connecting a first layer to a second layer within the 3DIC;

FIG. 3 is a simplified cross-sectional view of a 3DIC with a first exemplary expanded metal structure to tie-off a gate;

FIGS. 4A-4C illustrate exemplary top plan views of the metal structure of FIG. 3;

FIG. 5 is a simplified cross-sectional view of a 3DIC with a second exemplary expanded metal structure to tie-off a gate;

FIG. 6 is an exemplary top plan view of the metal structure of FIG. 5;

FIG. 7 is an exemplary flow chart of a process for making the IC of FIG. 3 or 5; and

FIG. 8 is a block diagram of an exemplary processor-based system that can include the IC of FIG. 3 or 5.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include tie-off structures for middle-of-line (MOL) manufactured integrated circuits, and related methods. As a non-limiting example, the tie-off structure may be used to tie-off a drain or source of a transistor to the gate of the transistor, such as provided in a dummy gate used for isolation purposes. In this regard in one embodiment, a MOL stack is provided that includes a metal gate connection is coupled to a metal layer through a metal structure disposed in and above a dielectric layer above a gate associated with the metal gate connection. By coupling the metal gate connection to the metal layer, the gate may be coupled or “tied-off” to a source or drain element of a transistor of which the gate is an element. As an example, moving the coupling to in and above the dielectric layer of the MOL stack helps avoid the need to etch the metal gate connection provided below the dielectric layer to provide sufficient connectivity between the metal layer and the metal gate connection, thus simplifying the manufacturing of integrated circuits (ICs), particularly at low nanometer node sizes.

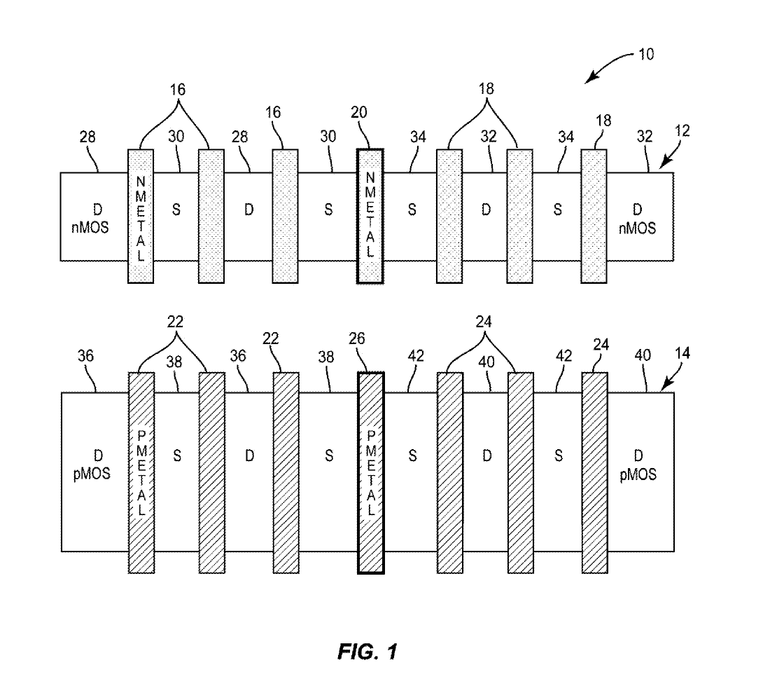

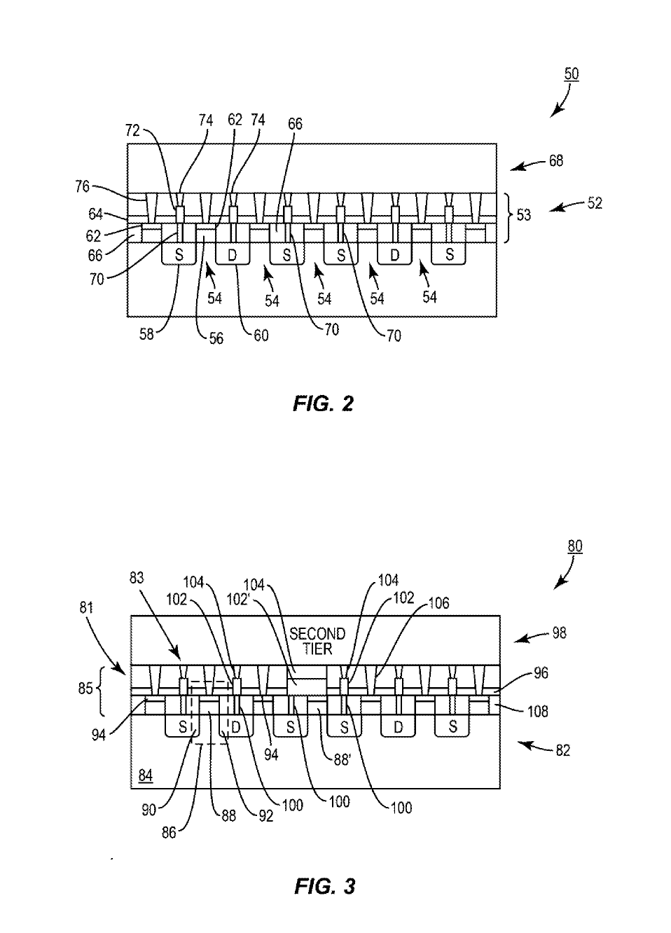

Before discussing exemplary MOL stacks that include a metal gate connection is coupled to a metal layer through a metal structure disposed in and above a dielectric layer above a gate associated with the metal gate connection to provide a MOL tie-off structure, FIGS. 1 and 2 are first discussed below to discuss exemplary ICs. Exemplary MOL stacks that include a metal gate connection is coupled to a metal layer through a metal structure disposed in and above a dielectric layer above a gate associated with the metal gate connection to provide a MOL tie-off structure are discussed below starting at FIG. 3.

In this regard, FIG. 1 illustrates a complementary metal oxide semiconductor (CMOS) device 10 having a first active area 12 and a second active area 14. The first active area 12 may have an n-metal (nMOS) work area and the second active area 14 may have a p-metal (pMOS) work area (or vice versa), as is well understood. A plurality of transistors is formed over the first active area 12 by placing gates 16 and 18 on either side of a dummy gate 20. Likewise, a plurality of transistors is formed over the second active area 14 by placing gates 22 and 24 on either side of dummy gate 26. Drains (D) 28 and sources (S) 30 are formed in association with gates 16, while drains 32 and sources 34 are formed in association with gates 18. Likewise, drains 36 and sources 38 are formed in association with gates 22 and drains 40 and sources 42 are formed in association with gates 24.

To assist in isolating the transistors from one another, the dummy gates 20 and 26 may be tied-off to either a source or drain. As used herein, “tie-off” is defined to be “electrically coupled.” While dummy gates 20 and 26 may benefit from such tie-off, it should be appreciated that other gates may also benefit from tie-off if necessitated by design decisions, and the present disclosure may be used in such situations as well. As the size of ICs continues to diminish, the ease with which such tie-offs are effectuated is also diminished. The difficulty with which tie-offs are made is exacerbated in three-dimensional (3D) IC (3DIC).

In this regard, FIG. 2 illustrates a conventional 3DIC 50 with a first tier 52 of active components provided in a MOL layer 53. In an exemplary aspect, the active components may be transistors 54 with gates 56, sources (S) 58, and drains (D) 60. The transistors 54 are each formed as a MOL stack, as shown for one transistor 54 in FIG. 2. A metal gate connection 62 may overlie the gate 56 or at least a portion of the gate 56 (e.g., a gate region). A dielectric layer 64 is positioned over the metal gate connection 62. The dielectric layer 64 may be formed from a material such as Silicon Nitride (SiN). An interlayer dielectric 66 that is distinct from and different than the dielectric layer 64 may fill the space around the gates 56 and prevent shorting between elements. In an exemplary aspect, the interlayer dielectric 66 is a silicon oxide material. Alternatively, the interlayer dielectric 66 may be a low-K dielectric or other like material.

With continued reference to FIG. 2, the 3DIC 50 may include a second tier 68 with additional active elements (not illustrated). The second tier 68 may be positioned above the dielectric layer 64. Interconnections between first tier 52 and second tier 68 may be effected by a combination of metal layers and vias and may be formed as part of a MOL process. In an exemplary aspect, a first metal layer 70 is positioned beneath the dielectric layer 64 and extends up from a source 58 (or a drain 60) to the dielectric layer 64. A second metal layer 72 extends through the dielectric layer 64 and is electrically coupled to the first metal layer 70. A via 74 couples the second metal layer 72 to active elements in the second tier 68. Likewise, a via 76 may extend through the dielectric layer 64 to the metal gate connection 62 to couple the gates 56 to active elements in the second tier 68. As noted above, as the size of the ICs gets smaller, it is increasingly difficult to tie-off a metal gate connection 62 to a source 58 or a drain 60.

In this regard, FIG. 3 is cross-sectional view of an IC in the form of a 3DIC 80 that includes MOL stacks 81 having a MOL tie-off structure 83 that includes a metal gate connection coupled to a metal layer through a metal structure disposed in and above a dielectric layer above a gate associated with the metal gate connection. With reference to FIG. 3, the IC in FIG. 3 is the 3DIC 80. The 3DIC 80 includes a first tier 82 in a MOL 85 having a substrate 84 on which one or more transistors 86 are formed. Each transistor 86 includes a gate 88, a source 90, and a drain 92. The gate 88 is coupled to the substrate 84. IN this exemplary aspect, by the virtue of the gate 88's physical position, the gate 88 contacts the substrate 84. The gate 88 is covered with a metal gate connection 94, and the metal gate connection 94 is covered with a dielectric layer 96. A second tier 98 is positioned above the dielectric layer 96 and has active elements (not illustrated) therein. Active elements within the second tier 98 are coupled to the transistors 86 (and other active elements in the first tier 82, if present) by metal layers and vias. In particular, a first metal layer 100 may be positioned below the dielectric layer 96 and couple to (or otherwise connect to) source 90 or drain 92. A second metal layer 102 may be positioned in and above the dielectric layer 96. The second metal layer 102 may couple the first metal layer 100 to vias 104 so that the source 90 and/or drain 92 may be coupled to elements in the second tier 98. Additional vias 106 may couple the metal gate connection 94 to elements in the second tier 98.

With continuing reference to FIG. 3, to tie-off a gate 88′ in the MOL stack 81, a second metal layer 102′ is expanded horizontally, such that it couples not only to the first metal layer 100, but also to the metal gate connection 94. Expanding or elongating the second metal layer 102′ in this fashion is relatively easy from a manufacturing point of view, in that the dielectric layer 96 is already etched to allow for the second metal layer 102 and the vias 106. When expanding the second metal layer 102′, neither the metal gate connection 94 nor the gate 88 needs to be further processed (e.g., etched) to facilitate electrical contact. Since placement of the second metal layer 102, 102′ takes place in the MOL process, front-end-of-line (FEOL) processes may be performed with standard lithography processes and without the need to modify such processes to create such tie-offs. A via, such as via 104 may couple to the second metal layer 102′ to finish the inter-tier connection. As with 3DIC 50, an interlayer dielectric 108 that is different from and distinct from the dielectric layer 96 and the interlayer dielectric 108 may be positioned under the dielectric layer 96.

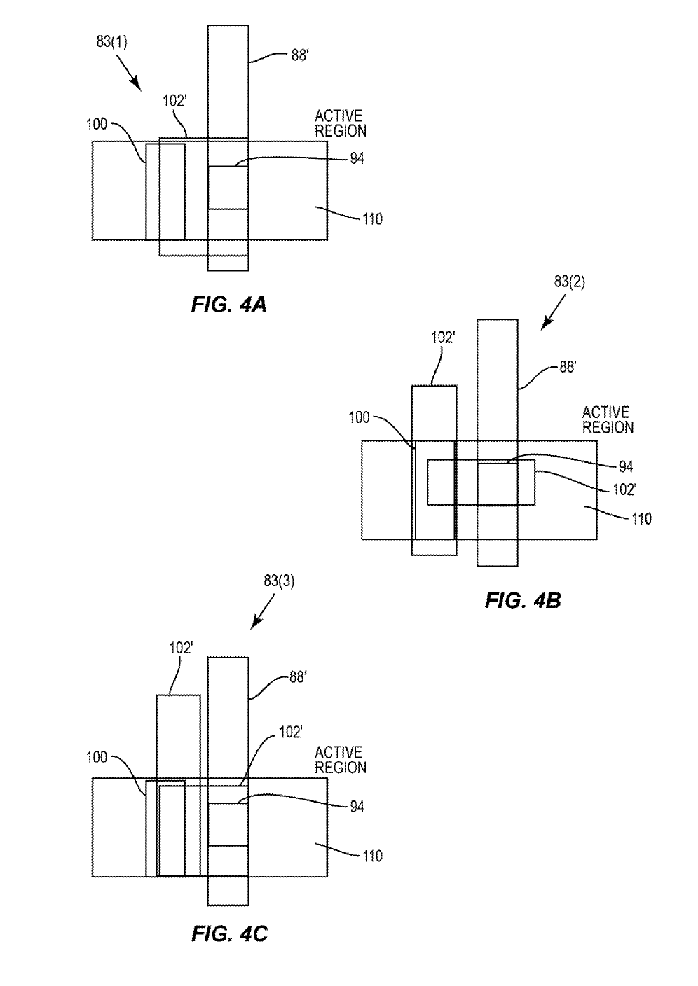

While FIG. 3 provides a cross-sectional view of the 3DIC 80 to illustrate an exemplary aspect of MOL tie-off structure 83 employing a metal gate connection coupled to the second metal layer 102′ disposed in and above a dielectric layer 96, FIGS. 4A-4C provide top plan views of MOL tie-off structures 83(1)-83(3) of the 3DIC 80 of FIG. 3 to illustrate possible arrangements of the second metal layer 102′ above an active region 110 of the 3DIC 80. Thus, as illustrated in FIG. 4A, a MOL tie-off structure 83(1) in the 3DIC 80 may provide for the second metal layer 102′ and may be generally square-rectangular in shape. Alternatively, a MOL tie-off structure 83(2) in the 3DIC 80 may provide for the second metal layer 102′ and may be generally T-shaped as illustrated in FIG. 4B, or generally L-shaped as illustrated in a MOL tie-off structure 83(3) provided in FIG. 4C. Still other geometries may be used without departing from the scope of the present disclosure.

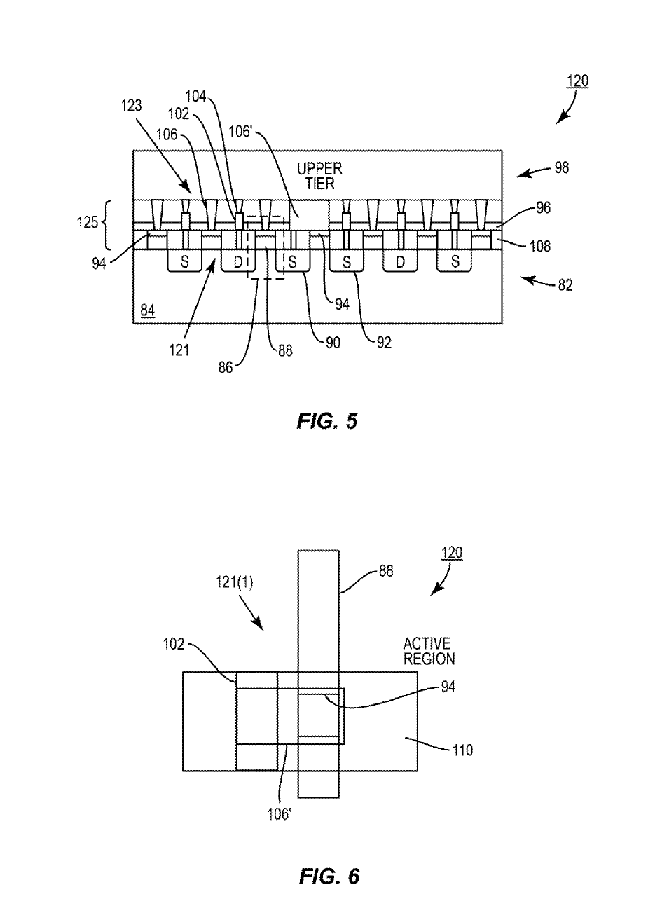

Further, instead of expanding a second metal layer 102′ in a MOL tie-off structure 83, a via may be expanded to tie-off the metal gate connection. In this regard, FIG. 5 illustrates an alternate 3DIC 120 that is substantially similar to 3DIC 80, but has a MOL tie-off structure 121 provided in a MOL stack 123 in a MOL 125 that includes a via 106′ that has been expanded to tie-off the metal gate connection 94 to the second metal layer 102 to tie off the first metal layer 100 to the metal gate connection 94. Likewise, FIG. 6 illustrates a top plan view of a MOL tie-off structure 121(1) that can be provided as the MOL tie-off structure 121 in FIG. 5, wherein the via 106′ is shown in a general T-shaped configuration relative to the first metal layer 100. Other geometries may also be used without departing from the scope of the present disclosure.

It should also be appreciated that the expanded via 106′ and the expanded second metal layer 102′ are metal structures, as that term is used herein. Likewise the expanded via 106′ and the expanded second metal layer 102′ are considered to be means for electrically coupling the metal gate connection 94 to the first metal layer 100.

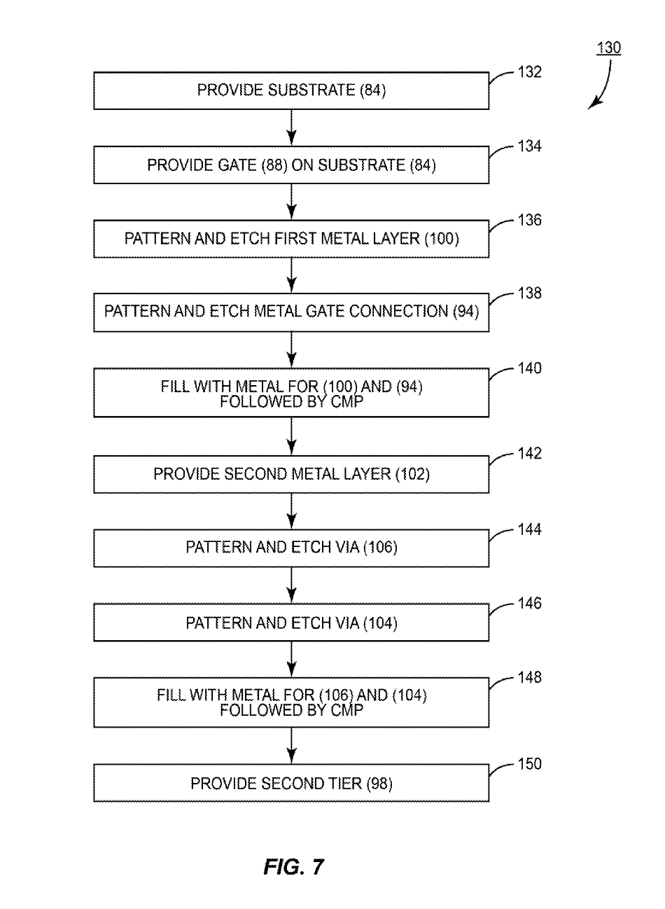

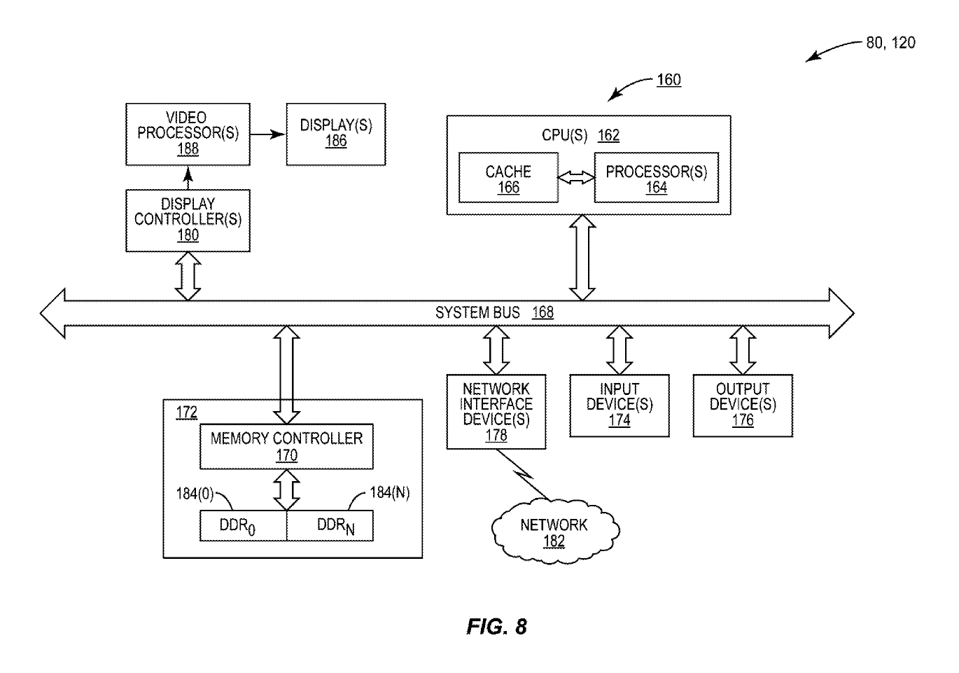

FIG. 7 illustrates an exemplary process 130 for manufacturing the 3DIC 80 or 120. The process 130 begins by providing a substrate 84 (block 132) and providing a gate 88 on the substrate 84 (block 134). The process 130 continues by patterning and etching a first metal layer 100 (block 136) and patterning and etching a metal gate connection 94 over the gate 88 (block 138). Once the pattern is etched, the resulting pattern may be filled with a metal, followed by chemical mechanical polishing (CMP) (block 140). It should be appreciated that the metal gate connection 94 and the first metal layer 100 may be made from the same material, and may be deposited or provided as part of the same step. It should be appreciated that blocks 132-140 may be performed as part of a FEOL manufacturing step. Subsequent blocks may be performed as part of an MOL manufacturing step.

With continued reference to FIG. 7, the process 130 continues by providing a second metal layer 102 (102′) (block 142). The vias 106 (106′) may then be patterned and etched (block 144) and the vias 104 may be patterned and etched (block 146). The vias 104, 106 (106′) may then be filled with metal followed by CMP (block 148) As noted above, the metal structure may be a second metal layer 102′, in which case it may be of an identical material as the first metal layer 100 and the metal gate connection 94. Alternatively, the metal structure may be a via 106′ and made from the same material as other vias. Such vias may be made through a tungsten process. After other vias and the second metal layer 102 are finished, a second tier 98 may be provided on top of the first tier 82 (block 150).

By planning the metal structure (e.g. second metal layer 102′ or via 106′) during a MOL process circuit designers have greater flexibility in arranging elements that need to be tied-off. Further, the overall manufacturing process is simplified since the metal gate connection and/or the gate do not have to be etched.

The MOL manufacturing techniques according to aspects disclosed herein, may be provided in or integrated into any processor-based device. Examples, without limitation, include: a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

In this regard, FIG. 8 illustrates an example of a processor-based system 160 that can employ the 3DIC 80 or 120 illustrated in FIGS. 3-6. In this example, the processor-based system 160 includes one or more central processing units (CPUs) 162, each including one or more processors 164. The CPU(s) 162 may have cache memory 166 coupled to the processor(s) 164 for rapid access to temporarily stored data. The CPU(s) 162 is coupled to a system bus 168 and can intercouple devices included in the processor-based system 160. As is well known, the CPU(s) 162 communicates with these other devices by exchanging address, control, and data information over the system bus 168. For example, the CPU(s) 162 can communicate bus transaction requests to a memory controller 170. Although not illustrated in FIG. 8, multiple system buses 168 could be provided, wherein each system bus 168 constitutes a different fabric.

Other devices can be connected to the system bus 168. As illustrated in FIG. 8, these devices can include a memory system 172, one or more input devices 174, one or more output devices 176, one or more network interface devices 178, and one or more display controllers 180, as examples. The input device(s) 174 can include any type of input device, including but not limited to input keys, switches, voice processors, etc. The output device(s) 176 can include any type of output device, including but not limited to audio, video, other visual indicators, etc. The network interface device(s) 178 can be any devices configured to allow exchange of data to and from a network 182. The network 182 can be any type of network, including but not limited to a wired or wireless network, private or public network, a local area network (LAN), a wide area network (WAN), wireless local area network (WLAN), BLUETOOTH® (BT), and the Internet. The network interface device(s) 178 can be configured to support any type of communications protocol desired. The memory system 172 can include one or more memory units 184(0-N).

The CPU(s) 162 may also be configured to access the display controller(s) 180 over the system bus 168 to control information sent to one or more displays 186. The display controller(s) 180 sends information to the display(s) 186 to be displayed via one or more video processors 188, which process the information to be displayed into a format suitable for the display(s) 186. The display(s) 186 can include any type of display, including but not limited to a cathode ray tube (CRT), a liquid crystal display (LCD), light emitting diode (LED) display, a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A middle-of-line (MOL) stack in an integrated circuit (IC), comprising:
a substrate;
a gate structure of a transistor overlying the substrate, the gate structure comprising:
a gate region coupled to the substrate; and
a metal gate connection overlying the gate region;
a first metal layer overlying the substrate, the first metal layer coupled to one of a drain or source of the transistor;
a dielectric layer overlying the gate structure and the first metal layer; and
a metal structure disposed in and above the dielectric layer, the metal structure electrically coupled to the metal gate connection and the first metal layer.

2. The MOL stack of claim 1, wherein the IC is comprised of a three-dimensional (3D) IC (3DIC).

3. The MOL stack of claim 1, wherein the metal structure comprises a second metal layer.

4. The MOL stack of claim 3, further comprising a via coupled to the second metal layer.

5. The MOL stack of claim 3, wherein the first metal layer, the second metal layer, and the metal gate connection are made from identical materials.

6. The MOL stack of claim 1, wherein the metal structure comprises a via.

7. The MOL stack of claim 6, wherein the via comprises a tungsten process via.

8. The MOL stack of claim 1, further comprising an interlayer dielectric distinct from the dielectric layer, the interlayer dielectric surrounding space between the gate region and the first metal layer.

9. The MOL stack of claim 1, wherein the transistor comprises a dummy transistor on an active region with active transistors.

10. The MOL stack of claim 1, wherein the gate region coupled to the substrate comprises a gate region contacting the substrate.

11. The MOL stack of claim 1 integrated into a semiconductor die.

12. The MOL stack of claim 1 integrated into a device selected from the group consisting of: a set top box; an entertainment unit; a navigation device; a communications device; a fixed location data unit; a mobile location data unit; a mobile phone; a cellular phone; a computer; a portable computer; a desktop computer; a personal digital assistant (PDA); a monitor, a computer monitor; a television; a tuner; a radio; a satellite radio; a music player; a digital music player; a portable music player; a digital video player; a video player; a digital video disc (DVD) player; and a portable digital video player.

13. A middle-of-line (MOL) stack in an integrated circuit (IC), comprising:
a substrate;
a gate structure of a transistor overlying the substrate, the gate structure comprising:
a gate region coupled to the substrate; and
a metal gate connection overlying the gate region;
a first metal layer overlying the substrate, the first metal layer coupled to one of a drain or source of the transistor;
a dielectric layer overlying the gate structure and the first metal layer; and
a means for electrically coupling the metal gate connection to the first metal layer, the means for electrically coupling disposed in and above the dielectric layer.

14. A method of forming a middle-of-line (MOL) stack in an integrated circuit (IC), comprising:
during a front-end-of-line (FEOL) process, providing a substrate;
during the FEOL process, providing a gate structure of a transistor overlying the substrate, the gate structure comprising:
a gate region coupled to the substrate; and
a metal gate connection overlying the gate region;
during the FEOL process, providing a first metal layer overlying the substrate, the first metal layer coupled to one of a drain or source of the transistor;
during the FEOL process, providing a dielectric layer overlying the gate structure and the first metal layer;
during a middle-of-line (MOL) process, providing a metal structure disposed in and above the dielectric layer; and
coupling the metal gate connection and the first metal layer with the metal structure.

15. The method of claim 14, wherein providing the metal structure comprises providing a second metal layer.

16. The method of claim 15, wherein providing the second metal layer comprises providing the second metal layer made from an identical material as the first metal layer and the metal gate connection.

17. The method of claim 14, wherein providing the metal structure comprises providing a via.

18. The method of claim 14, further comprising providing a via coupled to the metal structure.

19. The method of claim 18, wherein providing the via comprises providing the via through a tungsten process.

20. The method of claim 14, further comprising providing an interlayer dielectric distinct from and different from the dielectric layer around the metal gate connection and the first metal layer.

21. The method of claim 14, wherein the IC is a three-dimensional (3D) IC (3DIC).

22. The method of claim 14, wherein providing the gate structure comprises providing a dummy gate structure.

23. The method of claim 14, wherein providing the gate structure comprises providing the gate structure as part of a complementary metal oxide semiconductor (CMOS) device.

24. A middle-of-line (MOL) stack in an integrated circuit (IC), comprising:
a transistor comprising a gate and at least one of a source and a drain;
a first metal layer coupled to the at least one of the source and the drain;
a gate connection coupled to the gate;
a dielectric layer above the transistor, the first metal layer and the gate connection; and
a metal structure positioned in and above the dielectric layer electrically coupling the first metal layer with the gate connection.

25. The MOL stack of claim 24, further comprising an interlayer dielectric distinct from and different than the dielectric layer positioned around the gate and above the at least one of the source and the drain.
